(19) United States
(12) Patent Application Publication
(10) Pub. No.: US 2022/0262862 A1
(43) Pub. Date: Aug. 18, 2022

(54) IMAGE SENSOR PIXEL

(71) Applicant: ISORG, Limoges CEDEX 3 (FR)

(72) Inventors: Camille DUPOIRON, GRENOBLE (FR); Benjamin BOUTHINON, GRENOBLE (FR)

(21) Appl. No.: 17/627,454

(22) PCT Filed: Jul. 16, 2020
(86) PCT No.: PCT/EP2020/070073

§ 371 Date: Jan. 14, 2022

(30) Foreign Application Priority Data
Jul. 19, 2019 (FR) FR19/08252

(51) Int. Cl. H01L 27/30; H01L 51/44

(52) U.S. Cl. CPC H01L 27/307; H01L 51/441

(57) ABSTRACT

A pixel includes a CMOS support and at least two organic photodetectors. A same lens is vertically in line with the organic photodetectors.

The present patent application claims the priority benefit of French patent application FR19/08252, which is herein incorporated by reference.

### FIELD

The present disclosure relates to an image sensor or electronic imager.

### BACKGROUND

Image sensors are currently used in many fields, in particular in electronic devices. Image sensors are particularly present in man-machine interface applications or in image capture applications. The fields of use of such image sensors particularly are, for example, smart phones, motors vehicles, drones, robotics, and virtual or augmented reality systems.

In certain applications, a same electronic device may have a plurality of image sensors of different types. Such a device may thus comprise, for example, a first color image sensor, a second infrared image sensor, a third image sensor enabling to estimate a distance, relative to the device, of different points of a scene or of a subject, etc.

Such a multiplicity of image sensors embarked in a same device is, by nature, little compatible with current constraints of miniaturization of such devices.

### SUMMARY

There is a need to improve existing image sensors.

An embodiment overcomes all or part of the disadvantages of known image sensors.

An embodiment provides a pixel comprising:
a CMOS support; and
at least two organic photodetectors,
where a same lens is vertically in line with said organic photodetectors.

An embodiment provides an image sensor comprising a plurality of pixels such as described.

An embodiment provides a method of manufacturing such a pixel or such an image sensor, comprising steps of:
providing a CMOS support;
forming at least two organic photodetectors per pixel;
forming a same lens vertically in line with the organic photodetectors of the or of each pixel.

According to an embodiment, said organic photodetectors are coplanar.

According to an embodiment, said organic photodetectors are separated from one another by a dielectric.

According to an embodiment, each organic photodetector comprises a first electrode, separate from first electrodes of the other organic photodetectors, formed at the surface of the CMOS support.

According to an embodiment, each first electrode is coupled, preferably connected, to a readout circuit, each readout circuit preferably comprising three transistors formed in the CMOS support.

According to an embodiment, said organic photodetectors are capable of estimating a distance by time of flight.

According to an embodiment, the pixel or the sensor such as described is capable of operating:
in a portion of the infrared spectrum;
in structured light;
in high dynamic range imaging, HDR; and/or
with a background suppression.

According to an embodiment, each pixel further comprises, under the lens, a color filter giving way to electromagnetic waves in a frequency range of the visible spectrum and in the infrared spectrum.

According to an embodiment, the image sensor such as described is capable of capturing a color image.

According to an embodiment, each pixel exactly comprises:
a first organic photodetector;
a second organic photodetector; and
two third organic photodetectors.

According to an embodiment, for each pixel, the first organic photodetector, the second organic photodetector, and the third organic photodetectors have a square shape and are jointly inscribed within a square.

According to an embodiment, for each pixel:
the first organic photodetector is connected to a second electrode;
the second organic photodetector is connected to a third electrode; and
the third organic photodetectors are connected to a same fourth electrode.

According to an embodiment:
the first organic photodetector and the second organic photodetector comprise a first active layer made of a same first material; and
the third organic photodetectors comprise a second active layer made of a second material.

According to an embodiment, the first material is identical to the second material, said material being capable of absorbing the electromagnetic waves of the visible spectrum and of part of the infrared spectrum.

According to an embodiment, the first material is different from the second material, said first material being capable of absorbing the electromagnetic waves of part of the infrared spectrum and said second material being capable of absorbing the electromagnetic waves of the visible spectrum.

According to an embodiment:
the second electrode is common to all the first organic photodetectors of the pixels of the sensor;
the third electrode is common to all the second organic photodetectors of the pixels of the sensor; and
the fourth electrode is common to all the third organic photodetectors of the pixels of the sensor.

### BRIEF DESCRIPTION OF THE DRAWINGS

The foregoing and other features and advantages of the present invention will be discussed in detail in the following non-limiting description of specific embodiments and implementation modes in connection with the accompanying drawings, in which:

FIG. 1 is a partial simplified exploded perspective view of an embodiment of an image sensor;

FIG. 2 is a partial simplified top view of the image sensor of FIG. 1;

FIG. 3 is an electric diagram of an embodiment of the readout circuits of a pixel of the image sensor of FIGS. 1 and 2;

FIG. 4 is a timing diagram of signals of an example of operation of the image sensor having the readout circuits of FIG. 3;

FIG. 5 is a partial simplified cross-section view of a step of an implementation mode of a method of forming the image sensor of FIGS. 1 and 2;

FIG. 6 is a partial simplified cross-section view of another step of the implementation mode of the method of forming the image sensor of FIGS. 1 and 2;

FIG. 7 is a partial simplified cross-section view of still another step of the implementation mode of the method of forming the image sensor of FIGS. 1 and 2;

FIG. 8 is a partial simplified cross-section view of still another step of the implementation mode of the method of forming the image sensor of FIGS. 1 and 2;

FIG. 9 is a partial simplified cross-section view of still another step of the implementation mode of the method of forming the image sensor of FIGS. 1 and 2;

FIG. 10 is a partial simplified cross-section view of still another step of the implementation mode of the method of forming the image sensor of FIGS. 1 and 2;

FIG. 11 is a partial simplified cross-section view of still another step of the implementation mode of the method of forming the image sensor of FIGS. 1 and 2;

FIG. 12 is a partial simplified cross-section view of still another step of the implementation mode of the method of forming the image sensor of FIGS. 1 and 2;

FIG. 13 is a partial simplified cross-section view of still another step of the implementation mode of the method of forming the image sensor of FIGS. 1 and 2;

FIG. 14 is a partial simplified cross-section view of still another step of the implementation mode of the method of forming the image sensor of FIGS. 1 and 2;

FIG. 15 is a partial simplified cross-section view of still another step of the implementation mode of the method of forming the image sensor of FIGS. 1 and 2;

FIG. 16 is a partial simplified cross-section view of still another step of the implementation mode of the method of forming the image sensor of FIGS. 1 and 2;

FIG. 17 is a partial simplified cross-section view along plane CC of the image sensor of FIGS. 1 and 2;

FIG. 18 illustrates, in views (A), (B), and (C), an embodiment of electrodes of the image sensor of FIGS. 1 and 2;

FIG. 19 is a partial simplified cross-section view of a step of another implementation mode of a method of forming the image sensor of FIGS. 1 and 2;

FIG. 20 is a partial simplified cross-section view of another step of the other implementation mode of the method of forming the image sensor of FIGS. 1 and 2;

FIG. 21 is a partial simplified cross-section view of still another step of the other implementation mode of the method of forming the image sensor of FIGS. 1 and 2;

FIG. 22 is a partial simplified cross-section view of still another step of the other implementation mode of the method of forming the image sensor of FIGS. 1 and 2;

FIG. 23 is a partial simplified cross-section view of still another step of the other implementation mode of the method of forming the image sensor of FIGS. 1 and 2;

FIG. 24 is a partial simplified cross-section view of still another step of the other implementation mode of the method of forming the image sensor of FIGS. 1 and 2; and

FIG. 25 is a partial simplified cross-section view of another embodiment of an image sensor.

### DESCRIPTION OF THE EMBODIMENTS

Like features have been designated by like references in the various figures. In particular, the structural and/or functional elements common to the different embodiments and implementation modes may be designated with the same reference numerals and may have identical structural, dimensional, and material properties.

For clarity, only those steps and elements which are useful to the understanding of the described embodiments and implementation modes have been shown and will be detailed. In particular, what use is made of the image sensors described hereafter has not been detailed.

Unless specified otherwise, when reference is made to two elements connected together, this signifies a direct connection without any intermediate elements other than conductors, and when reference is made to two elements coupled together, this signifies that these two elements can be connected or they can be coupled via one or more other elements.

In the present disclosure, it is considered, unless specified otherwise, that the terms “insulating” and “conductive” respectively signify “electrically insulating” and “electrically conductive”.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an image sensor in a normal position of use.

Unless specified otherwise, the expressions “around”, “approximately”, “substantially” and “in the order of” signify within 10%, and preferably within 5%.

The transmittance of a layer to a radiation corresponds to the ratio of the intensity of the radiation coming out of the layer to the intensity of the radiation entering the layer, the rays of the incoming radiation being perpendicular to the layer. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%.

In the following description, “visible light” designates an electromagnetic radiation having a wavelength in the range from 400 nm to 700 nm and “infrared radiation” designates an electromagnetic radiation having a wavelength in the range from 700 nm to 1 mm. In infrared radiation, one can particularly distinguish near infrared radiation having a wavelength in the range from 700 nm to 1.7 μm.

A pixel of an image corresponds to the unit element of the image captured by an image sensor. When the optoelectronic device is a color image sensor, it generally comprises, for each pixel of the color image to be acquired, at least three components. The three components each acquire a light radiation substantially in a single color, that is, in a wavelength range below 130 nm (for example, red, green, and blue). Each component may particularly comprise at least one photodetector.

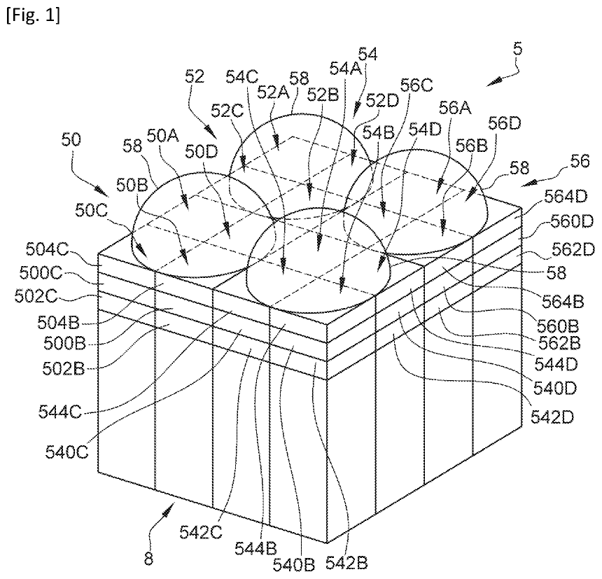

FIG. 1 is a partial simplified exploded perspective view of an embodiment of an image sensor 5.

Image sensor 5 comprises an array of coplanar pixels. For simplification, only four pixels 50, 52, 54, and 56 of image sensor 5 have been shown in FIG. 1, it being understood that, in practice, image sensor 5 may comprise more pixels. Image sensor 5 for example comprises several millions, or even several tens of millions of pixels.

According to this embodiment, pixels 50, 52, 54, and 56 are located at the surface of a CMOS support 8, for example, a piece of a silicon wafer on top and inside of which integrated circuits (not shown) have been formed in CMOS (Complementary Metal Oxide Semiconductor) technology. These integrated circuits form, in this example, an array of readout circuits associated with pixels 50, 52, 54, and 56 of image sensor 5. Readout circuit means an assembly of readout, addressing, and control transistors associated with each pixel.

In image sensor 5, each pixel comprises a first photodetector, designated with suffix “A”, a second photodetector, designated with suffix “B”, and two third photodetectors, designated with suffixes “C” and “D”. More particularly, in the example of FIG. 1:
pixel 50 comprises a first photodetector 50A, a second photodetector 50B, and two third photodetectors 50C and 50D;
pixel 52 comprises a first photodetector 52A, a second photodetector 52B, and two third photodetectors 52C and 52D;
pixel 54 comprises a first photodetector 54A, a second photodetector 54B, and two third photodetectors 54C and 54D; and
pixel 56 comprises a first photodetector 56A, a second photodetector 56B, and two third photodetectors 56C and 56D.

Photodetectors 50A, 50B, 50C, 50D, 52A, 52B, 52C, 52D, 54A, 54B, 54C, 54D, 56A, 56B, 56C, and 56D may correspond to organic photodiodes (OPD) or to organic photoresistors. In the rest of the disclosure, it is considered that the photodetectors of the pixels of image sensor 5 correspond to organic photodiodes.

In the simplified representation of FIG. 1, each photodetector comprises an active layer, or photosensitive layer, comprised or “sandwiched” between two electrodes. More particularly, in the example of FIG. 1 where only lateral surfaces of organic photodetectors 50B, 50C, 54B, 54C, 54D, 56B, and 56D are visible:
the second photodetector 50B is formed of an active layer 500B between a first electrode 502B and a second electrode 504B;
the third photodetector 50C is formed of an active layer 500C located between a first electrode 502C and a second electrode 504C;
the second photodetector 54B is formed of an active layer 540B between a first electrode 542B and a second electrode 544B;
the third photodetector 54C is formed of an active layer 504C between a first electrode 542C and a second electrode 544C;
the third photodetector 54D is formed of an active layer 540D between a first electrode 542D and a second electrode 544D;
the second photodetector 56B is formed of an active layer 560B between a first electrode 562A and a second electrode 564B; and
the third photodetector 56C is formed of an active layer 560D between a first electrode 562C and a second electrode 564D.

Similarly, in image sensor 5:
the first photodetector 50A is formed of an active layer 500A (not shown in FIG. 1) between a first electrode 502A (not shown in FIG. 1) and a second electrode 504A (not shown in FIG. 1);
the third first photodetector 50D is formed of an active layer 500D (not shown in FIG. 1) between a first electrode 502D (not shown in FIG. 1) and a second electrode 504D (not shown in FIG. 1);
the first photodetector 52A is formed of an active layer 520A (not shown in FIG. 1) between a first electrode 522A (not shown in FIG. 1) and a second electrode 524A (not shown in FIG. 1);
the second photodetector 52B is formed of an active layer 520B (not shown in FIG. 1) between a first electrode 522B (not shown in FIG. 1) and a second electrode 524B (not shown in FIG. 1);
the third photodetector 52C is formed of an active layer 520C (not shown in FIG. 1) between a first electrode 522C (not shown in FIG. 1) and a second electrode 524C (not shown in FIG. 1);
the third photodetector 52D is formed of an active layer 520D (not shown in FIG. 1) between a first electrode 522D (not shown in FIG. 1) and a second electrode 524D (not shown in FIG. 1);
the first photodetector 54A is formed of an active layer 540A (not shown in FIG. 1) between a first electrode 542A (not shown in FIG. 1) and a second electrode 544A (not shown in FIG. 1);
the first photodetector 56A is formed of an active layer 560A (not shown in FIG. 1) between a first electrode 562A (not shown in FIG. 1) and a second electrode 564A (not shown in FIG. 1); and
the third photodetector 56C is formed of an active layer 560C (not shown in FIG. 1) between a first electrode 562C (not shown in FIG. 1) and a second electrode 564C (not shown in FIG. 1).

In the rest of the disclosure, the first electrodes will also be designated with the expression “lower electrodes” while the second electrodes will also be designated with the expression “upper electrodes”.

According to an embodiment, the upper electrode of each organic photodetector forms an anode electrode while the lower electrode of each organic photodetector forms a cathode electrode.

The lower electrode of each photodetector of each pixel of image sensor 5 is individually coupled, preferably connected, to a readout circuit (not shown) of CMOS support 8. Each photodetector of image sensor 5 is accordingly individually addressed by its lower electrode. Thus, in image sensor 5, each photodetector has a lower electrode separate from the lower electrodes of all the other photodetectors. In other words, each photodetector of a pixel has a lower electrode separate:
from the other photodetector of the same pixel; and
from the other photodetectors of the other pixels.

Still in image sensor 5:
all the first photodetectors have a common first upper electrode;
all the second photodetectors have a common second upper electrode, separate from the first upper electrode common to the first photodetectors; and
all the third photodetectors have a third common upper electrode, separate from the first upper electrode common to all the first photodetectors and from the second electrode common to all the second photodetectors.

In image sensor 5, each pixel comprises a lens 58, also called microlens 58 due to its dimensions. Thus, in the simplified representation of FIG. 1, pixels 50, 52, 54, and 56 each comprise a lens 58. Each lens 58 thus totally covers the first, second, and third photodetectors of each pixel of image sensor 5. More particularly, lens 58 physically covers the upper electrodes of the first, second, and third photodetectors of the pixel.

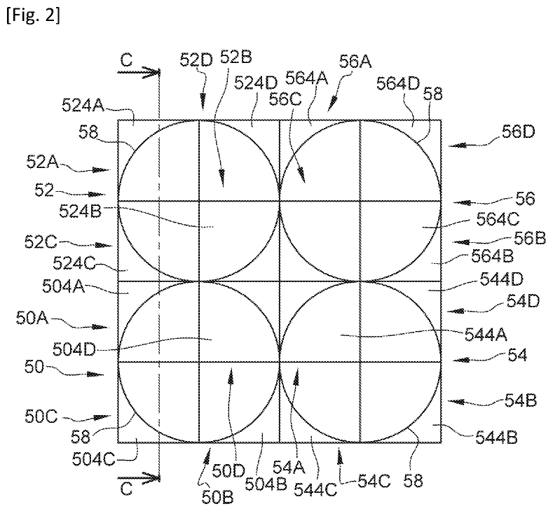

FIG. 2 is a partial simplified top view of the image sensor of FIG. 1.

In this top view, the first, second, and third photodetectors have been represented by squares and the microlenses have been represented by circles. More particularly, in FIG. 2:
a microlens 58 covers the upper electrodes 504A, 504B, 504C, and 504D of the photodetectors 50A, 50B, 50C, and 50D, respectively, of pixel 50;
a microlens 58 covers the upper electrodes 524A, 524B, 524C, and 524D of the photodetectors 52A, 52B, 52C, and 52D, respectively, of pixel 52;
a microlens 58 covers the upper electrodes 544A, 544B, 544C, and 544D of the photodetectors 54A, 54B, 54C, and 54D, respectively, of pixel 54; and
a microlens 58 covers the upper electrodes 564A, 564B, 564C, and 564D of the photodetectors 56A, 56B, 56C, and 56D, respectively, of pixel 56.

In practice, due to the intervals between electrodes which will appear from the discussion of the following figures, it can be considered that lenses 58 totally cover the respective electrodes of the pixels with which they are associated.

In image sensor 5, in top view in FIG. 2, the pixels are substantially square-shaped, preferably square shaped. All the pixels of image sensor 5 preferably have identical dimensions, to within manufacturing dispersions.

The square formed by each pixel of image sensor 5, in top view in FIG. 2, has a side length in the range from approximately 0.8 μm to 10 μm, preferably in the range from approximately 0.8 μm to 5 μm, more preferably in the range from 0.8 μm to 3 μm.

The first, second, and third photodetectors belonging to a same pixel (for example, the first photodetector 50A, the second photodetector 50B, and the third photodetectors 50C, 50D of first pixel 50) are square-shaped. The photodetectors have substantially the same dimensions and are jointly inscribed within the square formed by the pixel to which they belong.

The square formed by each photodetector of each pixel of image sensor 5 has a side length substantially equal to half the side length of the square formed by each pixel. Spaces are however formed between the first, second, and third photodetectors of each pixel, so that their respective lower electrodes are separate.

In image sensor 5, each microlens 58 has, in top view in FIG. 2, a diameter substantially equal, preferably equal to the side length of the square formed by the pixel to which is belongs. In the present embodiment, each pixel comprises a microlens 58. Each microlens 58 of image sensor 5 is preferably centered with respect to the square formed by the photodetectors that it covers.

As a variation, each microlens 58 may be replaced with another type of micrometer-range optical element, particularly a micrometer-range Fresnel lens, a micrometer-range index gradient lens, or a micrometer-range diffraction grating. Microlenses 58 are converging lenses each having a focal distance f in the range from 1 μm to 100 μm, preferably from 1 μm to 10 μm. According to an embodiment, all the microlenses 58 are substantially identical.

Microlenses 58 may be made of silica, of poly(methyl) methacrylate (PMMA), of a positive resist, of polyethylene terephthalate (PET), polyethylene naphthalate (PEN), of cyclo-olefin polymer (COP), of polydimethylsiloxane (PDMS)/silicone, or of epoxy resin. Microlenses 58 may be formed by flowing of resist blocks. Microlenses 58 may further be formed by molding on a layer of PET, PEN, COP, PDMS/silicone or epoxy resin.

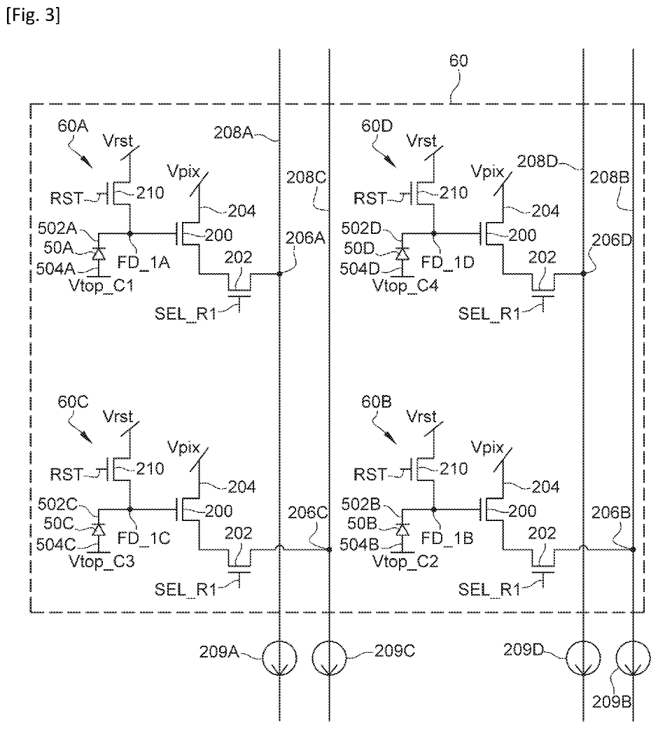

FIG. 3 is an electric diagram of an embodiment of readout circuits of a pixel of the image sensor 5 of FIGS. 1 and 2.

For simplification, FIG. 3 only considers the readout circuits associated with a single pixel of image sensor 5, for example, the pixel 50 of image sensor 5. In this example, each photodetector is associated with a readout circuit. More particularly, in FIG. 3:
the first photodetector 50A of pixel 50 is associated with a first readout circuit 60A;
the second photodetector 50B of pixel 50 is associated with a second readout circuit 60B;
the third photodetector 50C of pixel 50 is associated with a third readout circuit 60C; and
the third photodetector 50D of pixel 50 is associated with a fourth readout circuit 60D.

The first readout circuit 60A of the first photodetector 50A of pixel 50, the second readout circuit 60B of the second photodetector 50B of pixel 50, the third readout circuit 60C of the third photodetector 50C of pixel 50, and the fourth readout circuit 60D of the third photodetector 50D jointly form a readout circuit 60 of pixel 50.

According to this embodiment, each readout circuit 60A, 60B, 60C, 60D comprises three MOS transistors. Such a circuit is currently designated with its photodetector, by expression “3T sensor”. In particular, in the example of FIG. 3:
readout circuit 60A, associated with first photodetector 50A, comprises a follower-assembled MOS transistor 200, in series with a MOS selection transistor 202, between two terminals 204 and 206A;
readout circuit 60B, associated with second photodetector 50B, comprises a follower-assembled MOS transistor 200, in series with a MOS selection transistor 202, between two terminals 204 and 206B;
readout circuit 60C, associated with third photodetector 50C, comprises a follower-assembled MOS transistor 200, in series with a MOS selection transistor 202, between two terminals 204 and 206C; and
readout circuit 60D, associated with third photodetector 50D, comprises a follower-assembled MOS transistor 200, in series with a MOS selection transistor 202, between two terminals 204 and 206D.

Each terminal 204 is coupled to a source of a high reference potential, noted Vpix, in the case where the transistors of the readout circuits are N-channel MOS transistors. Each terminal 204 is coupled to a source of a low reference potential, for example, the ground, in the case where the transistors of the readout circuits are P-channel MOS transistors.

Terminal 206A is coupled to a first conductive track 208A. First conductive track 208A may be coupled to all the first photodetectors of the pixels of a same column. The first conductive track 208A is preferably coupled to all the first photodetectors of image sensor 5.

Similarly, terminal 206B is coupled to a second conductive track 208B. Second conductive track 208B may be coupled to all the second photodetectors of the pixels of a same column. Second conductive track 208B is preferably coupled to all the second photodetectors of image sensor 5. Second conductive track 208B is preferably separate from first conductive track 208A.

Similarly, terminal 206C is coupled to a third conductive track 208C and terminal 206D is coupled to a fourth conductive track 208D.

According to a preferred embodiment, third conductive track 208C and fourth conductive track 208D are connected together. Conductive tracks 208C, 208D may be coupled to all the third photodetectors of the pixels of a same column. Conductive tracks 208C, 208D are preferably coupled to all the third photodetectors of image sensor 5. Third conductive track 208C and fourth conductive track 208D are preferably separate from first conductive track 208A and from second conductive track 208B.

In the example of FIG. 3:
the first conductive track 208A is coupled, preferably connected, to a first current source 209A;
the second conductive track 208B is coupled, preferably connected, to a second current source 209B;
the third conductive track 208C is coupled, preferably connected, to a third current source 209C;
the fourth conductive track 208D is coupled, preferably connected, to a fourth current source 209D.

Current sources 209A, 209B, 209C, and 209D do not form part of the readout circuit 60 of pixel 50 of image sensor 5. In other words, the current sources 209A, 209B, 209C, and 209D of image sensor 5 are external to the pixels and readout circuits. According to the preferred embodiment where third conductive track 208C and fourth conductive track 208D are interconnected, the tracks are preferably coupled to a single current source 209C or 209D.

The gate of transistor 202 is intended to receive a signal, noted SEL_R1, of selection of pixel 50 in the case of the readout circuit 60 of pixel 50. It is assumed that the gate of the transistor 202 of the readout circuit of another pixel of image sensor 5, for example, the readout circuit of pixel 52, is intended to receive another signal, noted SEL_R2.

In the example of FIG. 3:
the gate of the transistor 200 associated with the first photodetector 50A of pixel 50 is coupled to a node FD_1A;
the gate of the transistor 200 associated with the second photodetector 50B of pixel 50 is coupled to a node FD_1B;
the gate of the transistor 200 associated with the second photodetector 50C of pixel 50 is coupled to a node FD_1C; and
the gate of the transistor 200 associated with the third photodetector 50D of pixel 50 is coupled to a node FD_1D.

Each node FD_1A, FD_1B, FD_1C, FD_1D is coupled, by a reset MOS transistor 210, to a terminal of application of a reset potential Vrst, which potential may be identical to potential Vpix. The gate of transistor 210 is intended to receive a signal RST for controlling the resetting of the photodetector, particularly enabling to reset node FD_1A, FD_1B, FD_1C, or FD_1D substantially to potential Vrst.

In the example of FIG. 3:
node FD_1A is connected to the cathode electrode 502A of the first photodetector 50A of pixel 50;
node FD_1B is connected to the cathode electrode 502B of the second photodetector 50B of pixel 50;
node FD_1C is connected to the cathode electrode 502C of the third photodetector 50C of pixel 50; and
node FD_1D is connected to the cathode electrode 502D of the third photodetector 50D of pixel 50.

Still in the example of FIG. 3:
the anode electrode 504A of the first photodetector 50A of pixel 50 is coupled to a source of a reference potential Vtop_C1;
the anode electrode 504B of the second photodetector 50B of pixel 50 is coupled to a source of a reference potential Vtop_C2;
the anode electrode 504C of the third photodetector 50C of pixel 50 is coupled to a source of a reference potential Vtop_C3; and
the anode electrode 504D of the third photodetector 50D of pixel 50 is coupled to a source of a reference potential Vtop_C4.

In image sensor 5, potential Vtop_C1 is applied on the first upper electrode common to all the first photodetectors. Potential Vtop_C2 is applied to the second upper electrode common to all the second photodetectors. Potential Vtop_C3 and potential Vtop_C4 are preferably equal and applied to the third upper electrode common to all the third photodetectors.

In the rest of the disclosure, the following notations are arbitrarily used:
VFD_1A for the voltage present at node FD_1A;
VFD_1B for the voltage present at node FD_1B;
VSEL_R1 for the voltage applied to the gate of the transistors 202 of pixel 50, that is, the voltage applied to the gate of the transistor 202 of first photodetector 50A, to the gate of the transistor 202 of second photodetector 50B, and to the gate of the transistors 202 of third photodetectors 50C, 50D;
VSEL_R2 for the voltage applied to the gate of the transistors 202 of pixel 52.

It is considered in the rest of the disclosure that the application of voltage VSEL_R1, respectively VSEL_R2, is controlled by the binary signal noted SEL_R1, respectively SEL_R2.

Other types of sensors, for example, so-called “4T” sensors, are known. The use of organic photodetectors advantageously enables to spare a transistor and to use a 3T sensor.

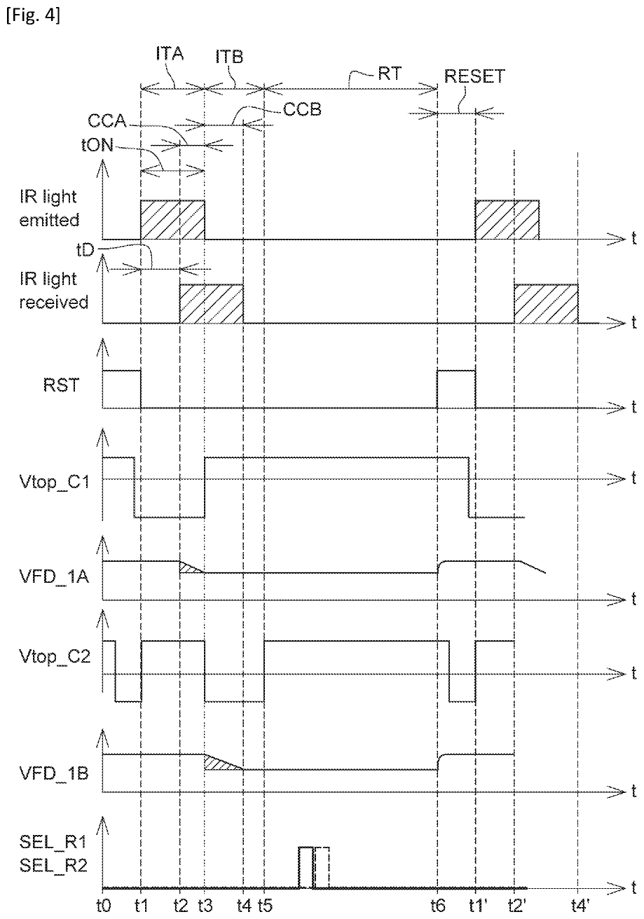

FIG. 4 is a timing diagram of signals of an example of operation of image sensor 5 having the readout circuit of FIG. 3.

The timing diagram of FIG. 4 more particularly corresponds to an example of operation of image sensor 5 in “time-of-flight” (ToF) mode. In this operating mode, the pixels of image sensor 5 are used to estimate a distance separating them from a subject (object, scene, face, etc.) placed or located opposite image sensor 5. To estimate this distance, it is started by emitting a light pulse towards the subject with an associated emitter system not described in the present text. Such a light pulse is generally obtained by briefly illuminating the subject with a radiation originating from a source, for example, a near infrared radiation originating from a light-emitting diode. The light pulse is then at least partially reflected by the subject, and then captured by image sensor 5. A time taken by the light pulse to make a return travel between the source and the subject is then calculated or measured. Image sensor 5 being advantageously located close to the source, this time corresponds to approximately twice the time taken by the light pulse to travel the distance separating the subject from image sensor 5.

The timing diagram of FIG. 4 illustrates an example of variation of binary signals RST and SEL_R1 as well as of the potentials Vtop_C1, Vtop_C2, VFD_1A, and VFD_1B of the first and second photodetectors of a same pixel of image sensor 5, for example, the first photodetector 50A and the second photodetector 50B of pixel 50. FIG. 4 also shows, in dotted lines, the binary signal SEL_R2 of another pixel of image sensor 5, for example, pixel 52. The timing diagram of FIG. 4 has been established considering that the MOS transistors of the readout circuit 60 of pixel 50 are N-channel transistors. For simplification, the driving of the third photodetectors 50C and 50D of pixel 50 of image sensor 5 is not considered in the timing diagram.

At a time t0, signal SEL_R1 is in the low state so that the transistors 202 of pixel 50 are off. A reset phase is then initiated. For this purpose, signal RST is maintained in the high state so that the reset transistors 210 of pixel 50 are on. The charges accumulated in photodiodes 50A and 50B are then discharged towards the source of potential Vrst.

Potential Vtop_C1 is, still at time to, in a high level. The high level corresponds to a biasing of the first photodetector 50A under a voltage greater than a voltage resulting from the application of a potential called “built-in potential”. The built-in potential is equivalent to a difference between a work function of the anode and a work function of the cathode. When potential Vtop_C1 is in the high level, the first photodetector 50A integrates no charges.

Before a time t1 subsequent to time t0, potential Vtop_C1 is set to a low level. This low level corresponds to a biasing of the first photodetector 50A under a negative voltage, that is, smaller than 0 V. This thus enables to first photodetector 50A to integrate photogenerated charges. What has been previously described in relation with the biasing of first photodetector 50A by potential Vtop_C1 transposes to the explanation of the operation of the biasing of the second photodetector 50B by potential Vtop_C2.

At time t1, it is started to emit a first infrared light pulse (IR light emitted) towards a scene comprising one or a plurality of objects, the distance of which is desired to be measured, which enables to acquire a depth map of the scene. The first infrared light pulse has a duration noted tON. At time t1, signal RST is set to the low state, so that the reset transistors 210 of pixel 50 are off, and potential Vtop_C2 is set to a high level.

Potential Vtop_C1 being at the low level, at time t1, a first integration phase, noted ITA, is started in the first photodetector 50A of pixel 50 of image sensor 5. The integration phase of a pixel designates the phase during which the pixel collects charges under the effect of an incident radiation.

At a time t2, subsequent to time t1 and separated from time t1 by a time period noted tD, a second infrared light pulse originating from the reflection of the first infrared light pulse by an object in the scene or by a point an object having its distance to pixel 50 desired to be measured, starts being received (IR light received). Time period tD thus is a function of the distance of the object to sensor 5. A first charge collection phase, noted CCA is then started, in first photodetector 50A. The first charge collection phase corresponds to a period during which charges are generated proportionally to the intensity of the incident light, that is, proportionally to the light intensity of the second pulse, in photodetector 50A. The first charge collection phase causes a decrease in the level of potential VFD_1A at node FD_1A of readout circuit 60A.

At a time t3, in the present example subsequent to time t2 and separated from time t1 by time period tON, the first infrared light pulse stops being emitted. Potential Vtop_C1 is simultaneously set to the high level, thus marking the end of the first integration phase, and thus of the first charge collection phase.

At the same time, potential Vtop_C2 is set to a low level. A second integration phase, noted ITB, is then started at time t3 in the second photodetector 50B of pixel 50 of image sensor 5. Given that the second photodetector 50B receives light originating from the second light pulse, a second charge collection phase, noted CCB, is started, still at time t3. The second charge collection phase causes a decrease in the level of potential VFD_1B at node FD_1B of readout circuit 60B.

At a time t4, subsequent to time t3 and separated from time t2 by a time period substantially equal to tON, the second light pulse stops being captured by the second photodetector 50B of pixel 50. The second charge collection phase then ends at time t4.

At a time t5, subsequent to time t4, potential Vtop_C2 is set to the high level. This thus marks the end of the second integration phase.

Between time t5 and a time t6, subsequent to time t5, a readout phase, noted RT, is carried out during which the quantity of charges collected by the photodiodes of the pixels of image sensor 5 is measured. For this purpose, the pixels rows of image sensor 5 are for example sequentially read. In the example of FIG. 4, signals SEL_R1 and SEL_R2 are successively set to the high state to alternately read pixels 50 and 52 of image sensor 5.

From time t6 and until a time t1′, subsequent to time t6, a new reset phase (RESET) is initiated. Signal RST is set to the high state so that the reset transistors 210 of pixel 50 are turned on. The charges accumulated in photodiodes 50A and 50B are then discharged towards the source of potential Vrst.

Time period tD, which separates the beginning of the first emitted light pulse from the beginning of the second received light pulse is calculated by means of the following formula:

$$tD = \frac{tON \times Δ VFD\_ 1 B}{Δ VFD\_ 1 A + ΔVFD\_ 1 B} \qquad [ Math 1 ]$$

In the above formula, the quantity noted ΔVFD_1A corresponds to a drop of potential VFD_1A during the integration phase of first photodetector 50A. Similarly, the quantity noted ΔVFD_1B corresponds to a drop of potential VFD_1B during the integration phase of second photodetector 50B.

At time t1′, a new distance estimation is initiated by the emission of a second light pulse. The new distance estimation comprises times t2′ and t4′ similar to times t2 and t4, respectively.

The operation of image sensor 5 has been illustrated hereabove in relation with an example of operation in time-of-flight mode, where the first and second photodetectors of a same pixel are driven in desynchronized fashion. An advantage of image sensor 5 is that it may also operate in other modes, particularly modes where the first and second photodetectors of a same pixel are driven in synchronized fashion. Image sensor 5 may for example be driven in global shutter mode, that is, image sensor 5 may also implement an image acquisition method where beginnings and ends of the integration phases of the first and second photodetectors are simultaneous.

An advantage of image sensor 5 thus is to be able to operate alternately according to different modes. Image sensor 5 may for example operate alternately in time-of-flight mode and in global shutter imaging mode.

According to an implementation mode, the readout circuits of the first and second photodetectors of image sensor 5 are alternately driven in other operating modes, for example, mode where image sensor 5 is capable of operating:
in a portion of the infrared spectrum;
in structured light;
in high dynamic range imaging (HDR), for example ascertaining that, for each pixel, the integration time of one of the first photodetector is greater than that of the second photodetector; and/or
with a background suppression.

Image sensor 5 may thus be used to performed different types of images with no loss of resolution, since the different imaging modes capable of being implemented by image sensor 5 use a same number of pixels. The use of image sensor 5, capable of integrating a plurality of functionalities in a same pixel array and readout circuits, particularly enables to respond to the current constraints of miniaturization of electronic devices, for example, smart phone design and manufacturing constraints.

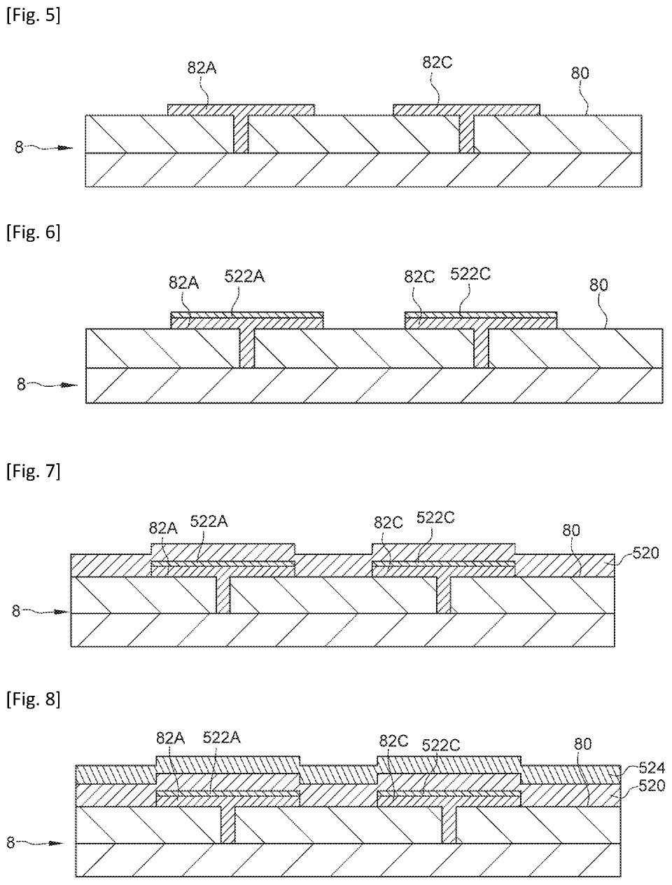

FIGS. 5 to 16 hereafter illustrate successive steps of an implementation mode of a method of forming the image sensor 5 of FIGS. 1 and 2. For simplification, what is discussed hereafter in relation with FIGS. 5 to 16 illustrates the forming of a portion of a pixel of image sensor 5, for example, the first photodetector 52A and the third photodetector 52C of the pixel 52 of image sensor 5. However, it should be understood that this method may be extended to the forming of any number of photodetectors and of pixels of an image sensor similar to image sensor 5.

FIG. 5 is a partial simplified cross-section view of a step of an implementation mode of a method of forming the image sensor 5 of FIGS. 1 and 2.

According to this embodiment, it is started by providing CMOS support 8 particularly comprising the readout circuits (not shown) of pixel 52. CMOS support 8 further comprises, at its upper surface 80, contacting elements 82A and 82B. Contacting elements 82A and 82C have, in cross-section view in FIG. 5, a “T” shape, where:
a horizontal portion extends on upper surface 80 of CMOS support 8; and
a vertical portion extends downwards from the upper surface 80 of CMOS support 8 to contact lower metallization levels (not shown) of CMOS support 8 coupled or connected to the readout circuits (not shown).

Contacting elements 82A and 82B are for example formed from conductive tracks formed on the upper surface 80 of CMOS support 8 (horizontal portions of contacting elements 82A and 82B) and from conductive vias (vertical portions of contacting elements 82A and 82B) contacting the conductive tracks. The conductive tracks and the conductive vias may be made of a metallic material, for example, silver (Ag), aluminum (Al), gold (Au), copper (Cu), nickel (Ni), titanium (Ti), and chromium (Cr), or of titanium nitride (TiN). The conductive tracks and the conductive vias may have a monolayer or multilayer structure. In the case where the conductive tracks have a multilayer structure, the conductive tracks may be formed by a stack of conductive layers separated by insulating layers. The vias then cross the insulating layers. The conductive layers may be made of a metallic material from the above list and the insulating layers may be made of silicon nitride (SiN) or of silicon oxide (SiO₂).

During this same step, CMOS support 8 is cleaned to remove possible impurities present at its surface 80. The cleaning is for example performed by plasma. The cleaning thus provides a satisfactory cleanness of CMOS support 3 before a series of successive depositions, detailed in relation with the following drawings, are performed.

In the rest of the disclosure, the implementation mode of the method described in relation with FIGS. 6 to 16 exclusively comprises performing operations above the upper surface 80 of CMOS support 8. The CMOS supports 8 of FIGS. 6 to 16 thus is preferably identical to the CMOS support 8 such as discussed in relation with FIG. 5 all along the process. For simplification, CMOS support 8 will not be detailed again in the following drawings.

FIG. 6 is a partial simplified cross-section view of another step of the implementation mode of the method of forming the image sensor 5 of FIGS. 1 and 2 from the structure such as described in relation with FIG. 5.

During this step, a deposition, at the surface of contacting elements 52A and 52C, of an electron injection material is performed. A material preferably selectively bonding to the surface of contacting elements 52A and 52C is preferably deposited to form a self-assembled monolayer (SAM). This deposition thus preferably or only covers the free upper surfaces of contacting elements 52A and 52C. One thus forms, as illustrated in FIG. 6:
the lower electrode 522A of the first organic photodetector 52A of pixel 52; and
the lower electrode 522C of the third organic photodetector 52C of pixel 52.

As a variant, a full plate deposition of an electron injection material having a sufficiently low lateral conductivity to avoid creating conduction paths between two neighboring contacting elements is performed.

Lower electrodes 522A and 522C form electron injection layers (EIL) and photodetectors 52A and 52C, respectively. Lower electrodes 522A and 522C are also called cathodes of photodetectors 52A and 52C. Lower electrodes 522A and 522C are preferably formed by spin coating or by dip coating.

The material forming lower electrodes 522A and 522C is selected from the group comprising:
a metal or a metallic alloy, for example, silver (Ag), aluminum (Al), lead (Pb), palladium (Pd), gold (Au), copper (Cu), nickel (Ni), tungsten (W), molybdenum (Mo), titanium or chromium (Cr), or an alloy of magnesium and silver (MgAg);
a transparent conductive oxide (TCO), particularly indium tin oxide (ITO), aluminum zinc oxide (AZO), gallium zinc oxide (GZO), an ITO/Ag/ITO multilayer, an ITO/Mo/ITO multilayer, a AZO/Ag/AZO multilayer, or a ZnO/Ag/ZnO multilayer;
a polyethyleneimine (PEI) polymer or a polyethyleneimine ethoxylated (PEIE), propoxylated, and/or butoxylated polymer;
carbon, silver, and/or copper nanowires;
graphene; and
a mixture of at least two of these materials.

Lower electrodes 522A and 522C may have a monolayer or multilayer structure.

FIG. 7 is a partial simplified cross-section view of still another step of the embodiment of the method of forming the image sensor 5 of FIGS. 1 and 2 from the structure such as described in relation with FIG. 6.

During this step, a non-selective deposition of a first layer 520 is performed on the upper surface side 80 of CMOS support 8. The deposition is called “full plate” deposition since it covers the entire upper surface 80 of CMOS support 8 as well as the free surfaces of contacting elements 52A, 52C and of lower electrodes 522A and 522C. The deposition of first layer 520 is preferably performed by spin coating.

According to this implementation mode, the first layer 520 is intended to form the future active layers 520A and 520C of the photodetectors 52A and 52C of pixel 52. The active layers 520A and 520C of the photodetectors 52A and 52C of pixel 52 preferably have a composition and a thickness identical to those of first layer 520.

First layer 520 may comprise small molecules, oligomers, or polymers. These may be organic or inorganic materials, particularly comprising quantum dots. First layer 520 may comprise an ambipolar semiconductor material, or a mixture of an N-type semiconductor material and of a P-type semiconductor material, for example in the form of stacked layers or of an intimate mixture at a nanometer scale to form a bulk heterojunction. The thickness of first layer 520 may be in the range from 50 nm to 2 μm, for example, in the order of 300 μm.

Examples of P-type semiconductor polymers capable of forming layer 520 are:
poly(3-hexylthiophene) (P3HT);
poly[N-9′-heptadecanyl-2,7-carbazole-alt-5,5-(4,7-di-2-thienyl-2′,1′,3′-benzothiadiazole] (PCDTBT);
poly[(4,8-bis-(2-ethylhexyloxy)-benzo[1,2-b;4,5-b′]dithiophene)-2,6-diyl-alt-(4-(2-ethylhexanoyl)-thieno[3,4-b]thiophene))-2,6-diyl] (PBDTTT-C);
poly[2-methoxy-5-(2-ethyl-hexyloxy)-1,4-pheny-lene-vinylene] (MEH-PPV); and
poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming layer 520 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

FIG. 8 is a partial simplified cross-section view of still another step of the embodiment of the method of forming the image sensor 5 of FIGS. 1 and 2 from the structure such as described in relation with FIG. 7.

During this step, a non-selective deposition of a second layer 524 is performed on the upper surface side 80 of CMOS support 8. The deposition is called “full plate” deposition since it covers the entire upper surface of first layer 520. The deposition of second layer 524 is preferably performed by spin coating.

According to this implementation mode, the second layer 524 is intended to form the future upper electrodes 524A and 524C of the photodetectors 52A and 52C of pixel 52. The upper electrodes 524A and 524C of the photodetectors 52A and 52C of pixel 52 preferably have a composition and a thickness identical to those of second layer 524.

Second layer 524 is at least partially transparent to the light radiation that it receives. Second layer 524 may be made of a transparent conductive material, for example, of transparent conductive oxide (TCO), of carbon nanotubes, of graphene, of a conductive polymer, of a metal, or of a mixture or an alloy of at least two of these compounds. Second layer 524 may have a monolayer or multilayer structure.

Examples of TCOs capable of forming second layer 524 are indium tin oxide (ITO), aluminum zinc oxide (AZO), and gallium zinc oxide (GZO), titanium nitride (TiN), molybdenum oxide (MoO₃), and tungsten oxide (WO₃). An example of a conductive polymer capable of forming second layer 524 is the polymer known as PEDOT:PSS, which is a mixture of poly(3,4)-ethylenedioxythiophene and of sodium poly(styrene sulfonate), and polyaniline, also called PAni. Examples of metals capable of forming second layer 524 are silver, aluminum, gold, copper, nickel, titanium, and chromium. An example of a multilayer structure capable of forming second layer 524 is a multilayer AZO and silver structure of AZO/Ag/AZO type.

The thickness of second layer 524 may be in the range from 10 nm to 5 μm, for example, in the order of 60 μm. In the case where second layer 524 is metallic, the thickness of second layer 524 is smaller than or equal to 20 nm, preferably smaller than or equal to 10 nm.

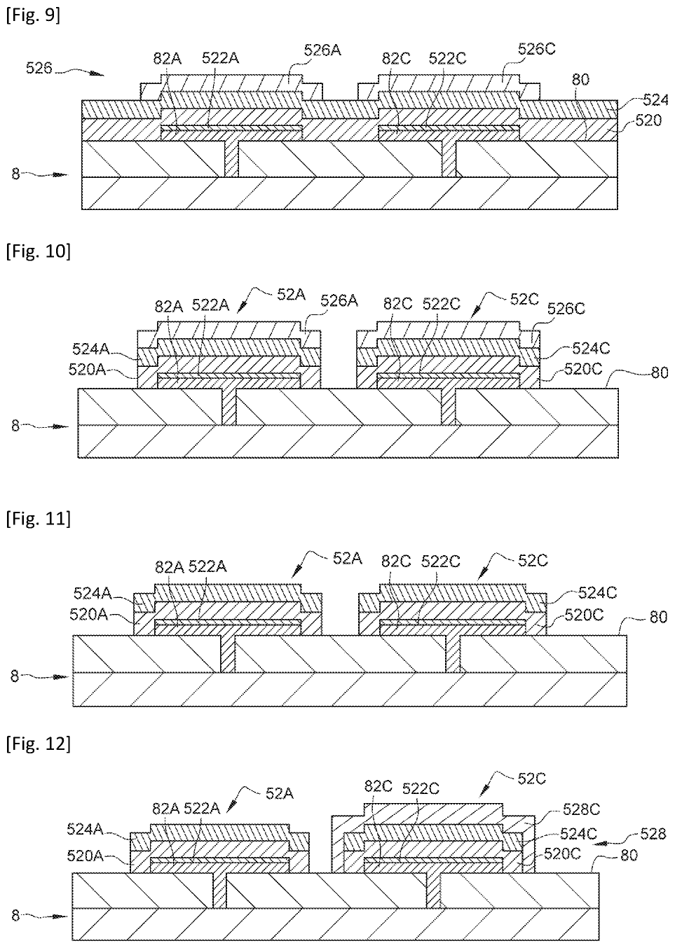

FIG. 9 is a partial simplified cross-section view of still another step of the embodiment of the method of forming the image sensor 5 of FIGS. 1 and 2 from the structure such as described in relation with FIG. 8.

During this step, the future photodetectors 52A and 52C are protected for subsequent steps. Such a protection is for example performed by:
a first operation comprising depositing, all over the upper surface of second layer 524, a third layer 526 (only two portions 526A and 526C of which remain at the end of the step and are shown), formed of a photolithography photoresist.
a second operation comprising illuminating, through a mask, the third photoresist layer 526; and
a third operation comprising removing, with a solvent, non-illuminated portions of third layer 526 (in the case of a third layer 526 formed of negative photoresist) to only keep, at the location of the first photodiode 52A, a first portion 526A (illuminated, still in the case of negative photoresist) of third layer 526 and to only keep, at the location of third photodiode 52C, a single portion 526C (illuminated in the case of negative photoresist) of third layer 526. In the case where third layer 526 is formed from positive photoresist, the illuminated portions of third layer 526 are removed.

FIG. 10 is a partial simplified cross-section view of still another step of the embodiment of the method of forming the image sensor 5 of FIGS. 1 and 2 from the structure such as described in relation with FIG. 9.

During this step, an etching operation is performed, for example, by reactive ion etching (RIE), to remove unprotected areas of second layer 524 and of first layer 520. An anisotropic etching is preferably performed so that the etching preferably (or selectively, or mostly) makes horizontal areas of second layer 524 and of first layer 520 disappear with respect to vertical areas of layers 524, 520.

Portions of layers 520, 524 which are not covered with first portion 526A and with second portion 526C of third layer 526 are thus removed to form, as illustrated in FIG. 10:
the active area 520A of the first photodetector 52A of pixel 52;
the upper electrode 524A of the first photodetector 52A of pixel 52;
the active area 520C of the third photodetector 52C of pixel 52; and
the upper electrode 524C of the third photodetector 52C of pixel 52.

Upper electrodes 524A and 524C form hole injection layers (HIL) of photodetectors 52A and 52C, respectively. Upper electrodes 524A and 524B are also called anodes of photodetectors 52A and 52C.

FIG. 11 is a partial simplified cross-section view of still another step of the embodiment of the method of forming the image sensor 5 of FIGS. 1 and 2 from the structure such as described in relation with FIG. 10.

During this step, the first portion 526A and the second portion 526C of third layer 526 are removed. This thus exposes:
the upper surface of the upper electrode 524A of the first photodetector 52A of pixel 52; and
the upper surface of the upper electrode 524C of the third photodetector 52C of pixel 52.

FIG. 12 is a partial simplified cross-section view of still another step of the embodiment of the method of forming the image sensor 5 of FIGS. 1 and 2 from the structure such as described in relation with FIG. 11.

During this step, the future photodetector 52C is protected by an encapsulation 528C. Encapsulation 528C is for example performed by:
a first operation comprising depositing, over the entire upper surface of the structure, a fourth layer 528 (only a portion 528C of which remains at the end of the step and is visible) made of a photo-patternable dielectric material;
a second operation comprising illuminating, through a mask, the fourth photo-patternable dielectric layer 528; and
a third operation comprising removing, with a solvent, non-illuminated portions of the fourth layer 528 to only keep, at the location of the third photodiode 52C, a portion 528C (illuminated) of fourth layer 528. The free upper and lateral surfaces of a stack formed by active layer 520A and the upper electrode 524C of third photodetector 52C are thus totally covered with the portion 528C of fourth layer 528. The material forming fourth layer 528 is then preferably resin of negative polarity.

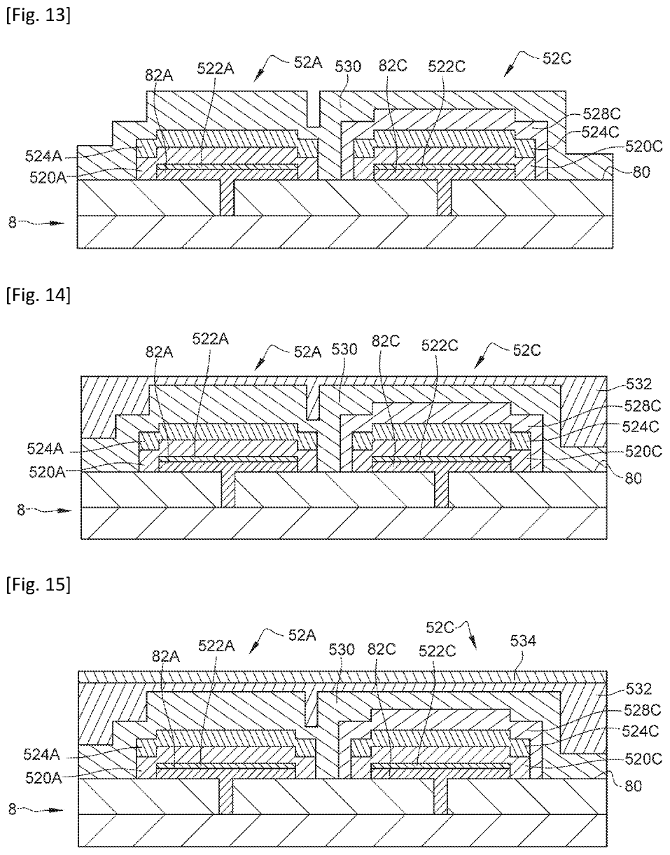

FIG. 13 is a partial simplified cross-section view of still another step of the embodiment of the method of forming the image sensor 5 of FIGS. 1 and 2 from the structure such as described in relation with FIG. 12.

During this step, a non-selective deposition of a fifth layer 530 is performed on the upper surface side 80 of CMOS support 8 (“full plate” deposition). According to this embodiment, fifth layer 530 is intended to continue the upper electrode 524A of the photodetector 52A of pixel 52.

According to an implementation mode, fifth layer 530 has a composition similar, preferably identical, to that of second layer 524 as discussed in relation with FIG. 8. Fifth layer 530 then behaves as a hole transport layer (HTL), also called access electrode.

According to another implementation mode, fifth layer 530 has a composition different from that of second layer 524.

FIG. 14 is a partial simplified cross-section view of still another step of the embodiment of the method of forming the image sensor 5 of FIGS. 1 and 2 from the structure such as described in relation with FIG. 13.

During this step, a non-selective deposition of a sixth layer 532 is performed on the upper surface side 80 of CMOS support 8. The deposition is called “full plate” deposition since it covers the entire upper surface of fifth layer 530. Sixth layer 532 is preferably a so-called “planarization” layer enabling to obtain a structure having a planar upper surface before the encapsulation of the photodetectors.

Sixth planarization layer 532 may be made of a polymer-based dielectric material. Planarization layer 532 may as a variant contain silicon nitride (SiN) or silicon oxide (SiO₂), this layer being obtained by sputtering, by physical vapor deposition (PVD) or by plasma-enhanced chemical vapor deposition (PECVD). As a variant, layer 532 is formed of a multilayer structure comprising alternately stacked silicon nitride layers and silicon oxide layers to form, for example, a SiN/SiO₂/SiN/SiO₂-type structure

Planarization layer 532 may also be made of a fluorinated polymer, particularly the fluorinated polymer commercialized under trade name “Cytop” by Bellex, of polyvinylpyrrolidone (PVP), of polymethyl methacrylate (PMMA), of polystyrene (PS), of parylene, of polyimide (PI), of acrylonitrile butadiene styrene (ABS), of polydimethylsiloxane (PDMS), of a photolithography resin, of epoxy resin, of acrylate resin, or of a mixture of at least two of these compounds.

FIG. 15 is a partial simplified cross-section view of still another step of the embodiment of the method of forming the image sensor 5 of FIGS. 1 and 2 from the structure such as described in relation with FIG. 14.

During this step, a seventh layer 534 is deposited all over the structure on the side of upper surface 80 of CMOS support 8. Seventh layer 534 aims at encapsulating the organic photodetectors of image sensor 5. Seventh layer 534 thus enables to avoid the degradation, due to an exposure to water or to the humidity contained in the ambient air, of the organic materials forming the photodetectors of image sensor 5. In the example of FIG. 15, seventh layer 534 covers the entire free upper surface of sixth planarization layer 532.

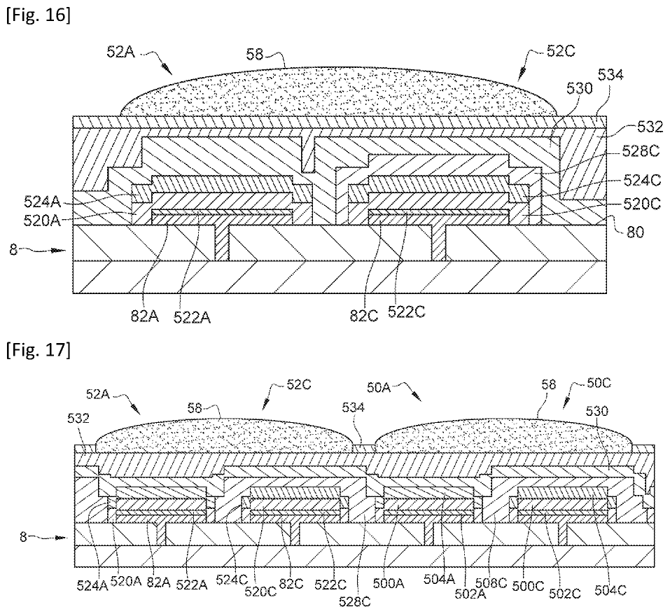

FIG. 16 is a partial simplified cross-section view of still another step of the embodiment of the method of forming the image sensor 5 of FIGS. 1 and 2 from the structure such as described in relation with FIG. 15.

During this step, the microlens 18 of pixel 52 is formed vertically in line with photodetectors 52A, 52B, 52C, and 52D (only photodetectors 52A and 52C are shown in FIG. 16).

As discussed in relation with FIG. 2, microlenses may be made of silica, of PMMA, of a positive photosensitive resin, of PET, of PEN, of COP, of PDMS/silicone, or of epoxy resin. Microlenses 58 may be formed by flowing of resist blocks. Microlenses 58 may further be formed by molding on a layer of PET, PEN, COP, PDMS/silicone or epoxy resin.

FIG. 17 is a partial simplified cross-section view along plane CC (FIG. 2) of the image sensor of FIGS. 1 and 2.

In FIG. 17, only the photodetectors 52A and 52C of pixel 52 and the photodetectors 50A and 50C of the pixel 50 of image sensor 5 have been shown. Pixels 50 and 52 belong to a same pixel column of image sensor 5. In the example of FIG. 17, the photodetectors 52A, 52C of pixel 52 and the photodetectors 50A, 50C of pixel 50 are separated from one another. Thus, along a same column of image sensor 5, each photodetector is insulated from the neighboring photodetectors.

In the example of FIG. 17:
active layers 500A, 500C, 520A, and 520C are separated from one another;
the lower electrodes 502A, 502C, 522A, and 522C are separated from one another;
the upper electrode 524A of the first photodetector 52A of pixel 52 and the upper electrode 524C of the third photodetector 52C of pixel 52 are separated by portion 528C of the fourth dielectric layer 528;
the upper electrode 504A of the first photodetector 50A of pixel 50 and the upper electrode 504C of the third photodetector 50C of pixel 50 are separated by portion 508C, similar to portion 528C, of the fourth dielectric layer 528; and
the upper electrode 524A of the first photodetector 52A of pixel 52 and the upper electrode 504C of the first photodetector 50A of pixel 50 are separated by fifth layer 530.

In other words, all the third photodetectors of the pixels belonging to a same column of pixels of image sensor 5 have a common upper electrode. In the example of FIG. 17, fifth layer 530 forms the third upper electrode common to the third photodetectors 50C and 52C.

According to a preferred implementation mode, the deposition of fifth layer 530 is performed so that fifth layer 530 also forms a common upper electrode of all the third photodetectors of the pixels of a same column. In the example of FIG. 17, fifth layer 530 then forms the third upper electrode common to the third photodetectors 50C, 50D of pixel 50 and to the third photodetectors 52C and 52D of pixel 52 as discussed in relation with FIG. 1.

FIG. 18 illustrates, in views (A), (B), and (C), an embodiment of electrodes of the image sensor 5 of FIGS. 1 and 2. View (A) here corresponds to an overlaying of views (B) and (C).

View (A) shows:
the upper electrodes 504A, 524A, 544A, and 564A of the first photodetectors 50A, 52A, 54A, and 56A of image sensor 5;
the upper electrodes 504B, 524B, 544B, and 564B of the second photodetectors 50B, 52B, 54B et 56B of image sensor 5;
the upper electrodes 504C, 524C, 544C, and 564C of the third photodetectors 50C, 52C, 54C, and 56C of image sensor 5; and
the upper electrodes 504D, 524D, 544D, and 564D of the third photodetectors 50D, 52D, 54D, and 56D of image sensor 5.

According to this embodiment, the upper electrodes of the third photodetectors are formed from a same layer 536, having two separate portions 5360 and 5362 shown in view (B). Portions 5360 and 5362 of layer 536 each form, in this example, a “zigzag” structure. Portion 5360 of layer 536 thus forms an electrode common to the third photodetectors of the pixels of a first column of image sensor 5. Similarly, portion 5362 of layer 536 forms an electrode common to the third photodetectors of the pixels of a second column of image sensor 5.

Portion 5360 of layer 536 thus couples the upper electrodes 504C, 504D, 524C, and 524D of the third photodetectors 50C, 50D, 52C, and 52D of the pixels 50 and 52 of the first column of image sensor 5. Similarly, portion 5362 of layer 536 couples the upper electrodes 544C, 544D, 564C, and 564D of the third photodetectors 54C, 54D, 56C, and 56D of the pixels 54 and 56 of the second column of image sensor 5.

The upper electrodes of the first photodetectors are formed from layer 530 (as discussed in relation with FIG. 17), two separate portions 5300 and 5302 of which are shown in view (C). Portions 5300 and 5302 of layer 530 each form, in this example, a strip. Portion 5300 of layer 530 thus forms an electrode common to the first photodetectors of the pixels of the first column of image sensor 5. Similarly, portion 5302 of layer 530 forms an electrode common to the first photodetectors of the pixels of the second column of image sensor 5.

Portion 5300 of layer 530 thus couples the upper electrodes 504A and 524A of the first photodetectors 50A and 52A of the pixels 50 and 52 of the first column of image sensor 5. Similarly, portion 5302 of layer 530 thus couples the upper electrodes 544A and 564A of the first photodetectors 54A and 56A of the pixels 54 and 56 of the second column of image sensor 5.

Similarly, the upper electrodes of the second photodetectors are formed from a same layer 538, two separate portions 5380 and 5382 of which are shown in view (C). Portions 5380 and 5382 of layer 538 each form, in this example, a strip. Portion 5380 of layer 538 thus forms an electrode common to the second photodetectors of the pixels of the first column of image sensor 5. Similarly, portion 5382 of layer 538 forms an electrode common to the second photodetectors of the pixels of the second column of image sensor 5.

Portion 5380 of layer 538 thus couples the upper electrodes 504B and 524B of the second photodetectors 50B and 52B of the pixels 50 and 52 of the first column of image sensor 5. Similarly, portion 5382 of layer 538 couples the upper electrodes 544B and 564B of the second photodetectors 54B and 56B of the pixels 54 and 56 of the second column of image sensor 5.

Layers 530, 536, and 538 are insulated from one another. Layer 536 and layers 530, 538 are preferably non-coplanar. This enables to ease the insulation between the different common upper electrodes of the photodetectors of image sensor 5.

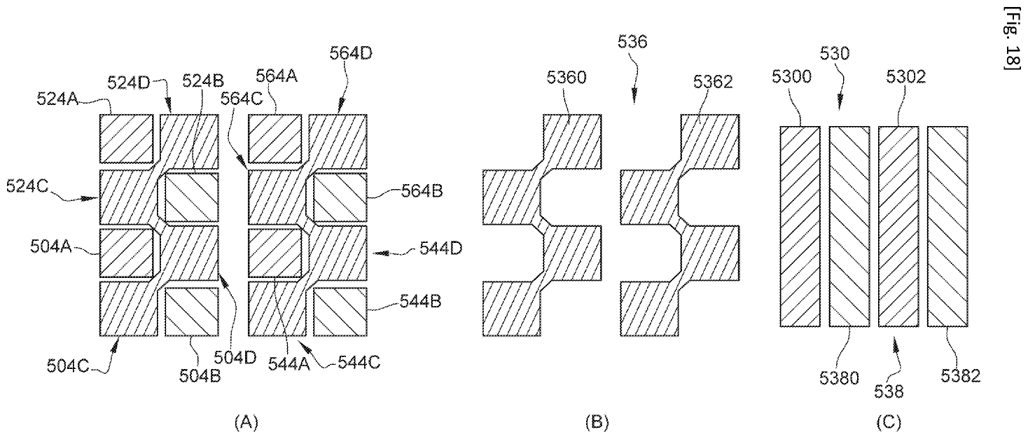

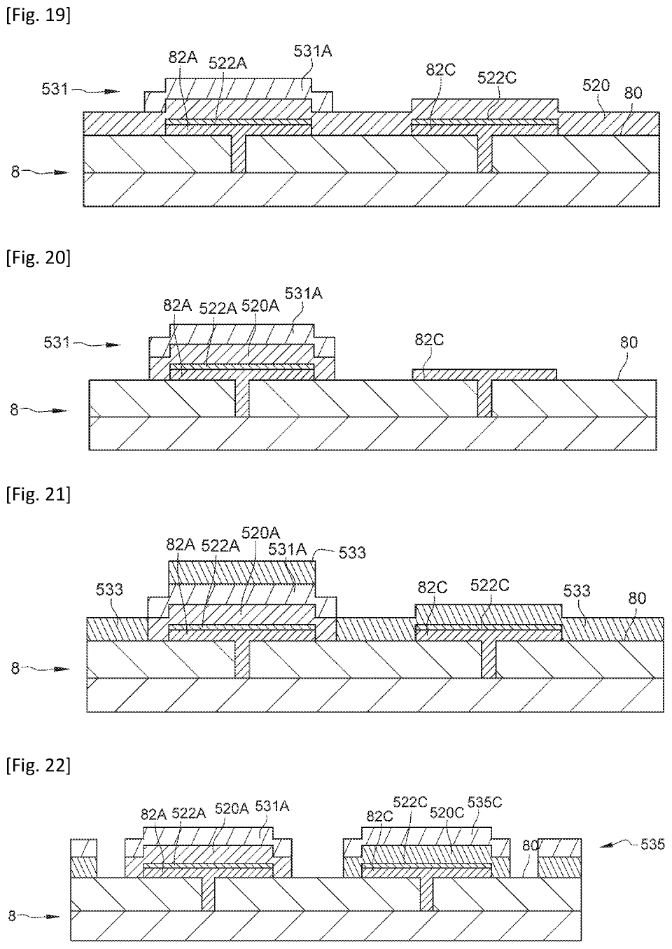

FIGS. 19 to 24 hereafter illustrate successive steps of another implementation mode of a method of forming the image sensor 5 of FIGS. 1 and 2. For simplification, what is discussed hereafter in relation with FIGS. 19 to 24 illustrates the forming of a portion of a pixel of image sensor 5, for example, the first photodetector 52A and the third photodetector 52C of the pixel 52 of image sensor 5. However, it should be understood that this method may be extended to the forming of any number of photodetectors and of pixels of an image sensor similar to image sensor 5.

The first steps of this other implementation mode are similar to the steps of the implementation mode previously described in relation with FIGS. 5 to 7. For simplification, these steps will not be detailed again hereafter.

FIG. 19 is a partial simplified cross-section view of a step of another implementation mode of a method of forming the image sensor of FIGS. 1 and 2 from the structure such as described in relation with FIG. 7.

During this step, the future photodetector 52A is protected for subsequent steps. Such a protection is for example performed by:
a first operation comprising depositing, all over the upper surface of first layer 520, an eighth layer 531 (only a portion 531A of which remain at the end of the step and is shown), formed of photolithography photoresist;
a second operation comprising illuminating, through a mask, the eighth photoresist layer 531; and
a third operation comprising removing, with a solvent, illuminated portions (in the case of an eighth layer 531 formed of negative photoresist) of eighth layer 531 to only keep, at the location of the first photodiode 52A, a portion 531A (non-illuminated, still in the case of a positive photoresist) of eighth layer 531.

FIG. 20 is a partial simplified cross-section view of another step of the other implementation mode of the method of forming the image sensor of FIGS. 1 and 2 from the structure such as described in relation with FIG. 19.

During this step, an etching operation is performed, for example, by a dry etching method (for example, a plasma etching of reactive ion etching type), to remove unprotected areas of first layer 520. An anisotropic etching is preferably performed so that the etching preferably (or selectively, or mostly) makes horizontal areas of first layer 520 disappear with respect to vertical areas of layer 520.

Portions of first layer 520 non-covered with portion 531A of eighth layer 531 as well as the lower electrode 522C of the future third photodetector 52C are thus removed. As illustrated in FIG. 20, the active layer 520A of the first photodetector 52A of pixel 52 is thus formed and the contacting element 82C of the future third photodetector 52C is exposed.

FIG. 21 is a partial simplified cross-section view of still another step of the other implementation mode of the method of forming the image sensor 5 of FIGS. 1 and 2 from the structure such as described in relation with FIG. 2.

During this step, a deposition is performed on contacting element 82C to restore the lower electrode 522C of the future third photodetector 52C. A material preferably selectively bonding to the surface contacting element 52C is preferably deposited to form a self-assembled monolayer (SAM). The deposition thus preferably or only covers the free upper surface of contacting element 52C.

A non-selective deposition of a ninth layer 533 is then performed on the upper surface side 80 of CMOS support 8. According to this implementation mode, the ninth layer 533 is intended to form the future active layers 520C and 520D of the photodetectors 52C and 52D of pixel 52. The active layers 520C and 520D of the photodetectors 52C and 52D of pixel 52 preferably have a composition and a thickness identical to those of first layer 533.

According to a preferred implementation mode, the composition of ninth layer 533 is different from that of first layer 520. First layer 520 for example has an absorption wavelength centered on the visible wavelength range while ninth layer 533 has, for example, an absorption wavelength of approximately 940 nm.

FIG. 22 is a partial simplified cross-section view of still another step of the other implementation mode of the method of forming the image sensor 5 of FIGS. 1 and 2 from the structure such as described in relation with FIG. 21.

During this step, a first operation comprising depositing on the upper surface side 80 of CMOS support 8 a tenth layer 535 (only a portion 535C of which remains at the end of the step and is shown), formed of a photolithography photoresist, is carried out. The same resist as that used at the step discussed in relation with FIG. 19 is used to form eighth layer 531. A second operation comprising illuminating, through a mask, this tenth photoresist layer, is then carried out. Then, illuminated portions (in the case of a tenth layer 535 made of a positive resist) of tenth layer 535 are removed by solvent to only keep, in particular, at the location of third photodiode 52C, a portion 535C (non-illuminated) of tenth layer 535.

Portions of ninth layer 533 non-protected by portion 535C of tenth layer 535 are then etched. Vertical openings located on either side of each of contacting elements 82A and 82C are thus formed in ninth layer 533. The active layer 520C of third photodetector 52C is thus formed.

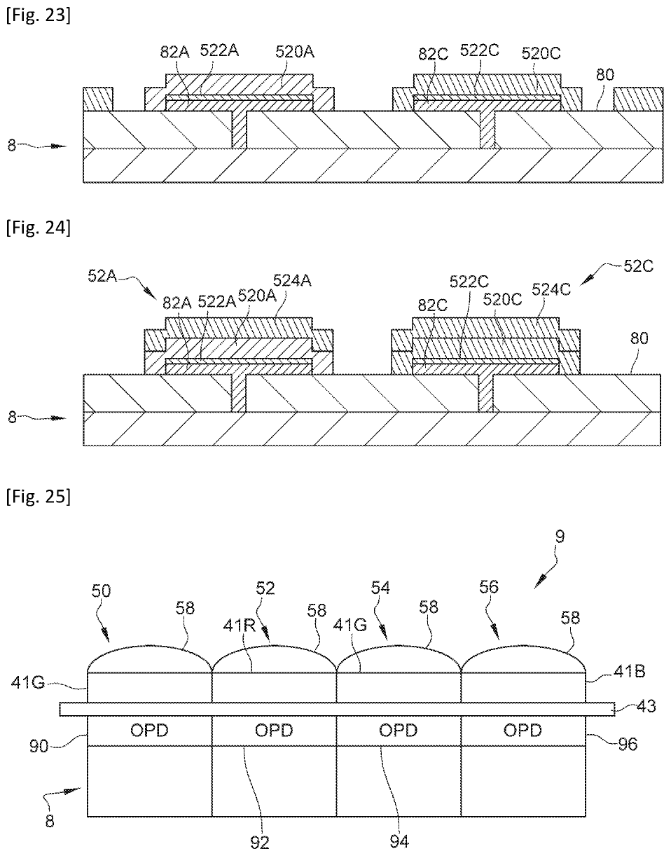

FIG. 23 is a partial simplified cross-section view of still another step of the other implementation mode of the method of forming the image sensor 5 of FIGS. 1 and 2 from the structure such as described in relation with FIG. 22.

During this step, the remaining portions of eighth layer 531 and of tenth layer 535 are removed, preferably by dipping into a solvent (stripping). The following are particularly removed:
portion 531A of eighth layer 531, which covers the active layer 520A of first photodetector 52A of pixel 52;
portion 535C of tenth layer 535, which covers the active layer 520C of the third photodetector 52C of pixel 52.

FIG. 24 is a partial simplified cross-section view of still another step of the other implementation mode of the method of forming the image sensor 5 of FIGS. 1 and 2 from the structure such as described in relation with FIG. 23.

During this step, the following are formed:
the upper electrode 524A of first photodetector 52A;
the upper electrode 524C of third photodetector 52C.

These electrodes are preferably formed as previously discussed in relation with FIGS. 8 to 11. The method of forming image sensor 5 is then carried on as previously discussed in relation with FIGS. 12 to 16.

FIG. 25 is a partial simplified cross-section view of another embodiment of an image sensor 9.

The image sensor 9 shown in FIG. 25 is similar to the image sensor 5 discussed in relation with FIGS. 1 and 2. Image sensor 9 differs from image sensor 5 mainly in that:
the pixels 50, 52, 54, and 56 of image sensor 9 belong to a same row or to a same column of image sensor 9 (while the pixels 50, 52, 54, and 56 of image sensor 5 (FIG. 1) are distributed on two different rows and two different columns of image sensor 5); and
each pixel 50, 52, 54, and 56 of image sensor 9 has a color filter 41R, 41G, or 41B under its microlens 58 and on a passivation layer 43. In other words, the four monochromatic pixels 50, 52, 54, and 56 arranged in a square in FIG. 1 are here placed side by side in FIG. 25.

More particularly, in the example of FIG. 25, image sensor 9 comprises:
a first green filter 41G, interposed between the microlens 58 of pixel 50 and passivation layer 43;
a red filter 41R, interposed between the microlens 58 of pixel 52 and passivation layer 43;
a second green filter 41G, interposed between the microlens 58 of pixel 54 and passivation layer 43; and
a blue filter 41B, interposed between the microlens 58 of pixel 56 and passivation layer 43.

According to this embodiment, the color filters 41R, 41G, and 41B of image sensor 9 give way to electromagnetic waves in frequency ranges different from the visible spectrum and give way to the electromagnetic waves of the infrared spectrum. Color filters 41R, 41G, and 41B may correspond to colored resin blocks. Each color filter 41R, 41G, and 41B is capable of giving way to the infrared radiation, for example, at a wavelength between 700 nm and 1 mm and, for at least some of the color filters, of giving way to a wavelength range of visible light.

For each pixel of a color image to be acquired, image sensor 9 may comprise:
at least one pixel (for example, pixel 56) having its color filter 41B capable of giving way to infrared radiation and blue light, for example, in the wavelength range from 430 nm to 490 nm;
at least one pixel (for example, pixels 50 and 54) having its color filter 41G capable of giving way to infrared radiation and blue light, for example, in the wavelength range from 510 nm to 570 nm; and
at least one pixel (for example, pixel 52) having its color filter 41R capable of giving way to infrared radiation and red light, for example, in the wavelength range from 600 nm to 720 nm.

Similarly to the image sensor 5 discussed in relation with FIGS. 1 and 2, each pixel 50, 52, 54, 56 of image sensor 9 has a first and a second photodetector, the first and second photodetectors being capable of estimating a distance by time of flight, and two third photodetectors capable of capturing an image. Each pixel thus comprises four photodetectors, very schematically shown in FIG. 25 by a same block (OPD). More particularly, in FIG. 25:
pixel 50 comprises four organic photodetectors (block 90, OPD);
pixel 52 comprises four organic photodetectors (block 92, OPD);
pixel 54 comprises four organic photodetectors (block 94, OPD); and
pixel 56 comprises four organic photodetectors (block 96, OPD).

The photodetectors of each pixel 50, 52, 54, and 56 are coplanar and each associated with a readout circuit as discussed in relation with FIG. 3. The readout circuits are formed on top of an inside of CMOS support 8. Image sensor 9 is thus capable, for example, of alternately performing time-of-flight distance estimates and color image captures.

According to an embodiment, the active layers of the first, second, and third photodetector of the pixels of image sensor 9 are made of a same material capable of absorbing the electromagnetic waves of the visible spectrum and of a portion of the infrared spectrum, preferably near infrared. Image sensor 9 can then be used to alternately obtain:
time-of-flight distance estimates due to the first and second photodetectors and by driving them, for example, as discussed in relation with FIG. 4; and
color images due to the third photodetectors by driving the third photodetectors, for example, in synchronized fashion.

An advantage of this embodiment is that image sensor then has a greater sensitivity since the four photodetectors of each pixel are used during the forming of the color image.

According to another embodiment, the active layers of the first and second photodetectors of the pixels of image sensor 9 are made of a material different from that forming the active layers of the third photodetectors. According to this embodiment:
the material forming the active layers of the first and second photodetectors is capable of absorbing the electromagnetic waves of a portion of the infrared spectrum, preferably near infrared; and
the material forming the active layers of the third photodetectors is capable of absorbing the electromagnetic waves of the visible spectrum, while being transparent to near infrared radiation.

Image sensor 9 can then be used to simultaneously or alternately obtain:
time-of-flight distance estimates due to the first and second photodetectors and by driving them, for example, as discussed in relation with FIG. 4; and
color images due to the third photodetectors by driving the third photodetectors, for example, in synchronized fashion.

An advantage of this other embodiment is that image sensor 9 is then capable of overlaying, on a color image, information resulting from the time-of-flight distance estimation. An implementation mode of the operation of image sensor 9 for example enabling to generate a color image of a subject and to include therein, for each pixel of the color image, information representative of the distance separating image sensor 9 from the area of the subject represented by the considered pixel, can thus be imagined. In other words, image sensor 9 may form a three-dimensional image of a surface of an object, of a face, of a scene, etc.

Various embodiments, implementation modes, and variations have been described. Those skilled in the art will understand that certain features of these various embodiments, implementation modes, and variants may be combined, and other variants will occur to those skilled in the art.

Finally, the practical implementation of the described embodiments, implementation modes, and variations is within the abilities of those skilled in the art based on the functional indications given hereabove. In particular, the adaptation of the driving of the readout circuits of image sensors 5 to 9 to other operating modes, for example, for the forming of infrared images with or without added light, the forming of images with a background suppression, and the forming of high-dynamic range images (simultaneous HDR), is within the abilities of those skilled in the art based on the above indications.

1. A pixel comprising:
a CMOS support; and
at least first and second organic photodetectors,
wherein a same lens is vertically in line with said organic photodetectors.

2. An image sensor comprising a plurality of pixels, each of the pixels comprising:
a CMOS support; and
at least first and second organic photodetectors,
wherein a same lens is vertically in line with said organic photodetectors.

3. A method of manufacturing the pixel according to claim 1, comprising steps of:
providing a CMOS support;
forming at least two organic photodetectors; and
forming a same lens vertically in line with the organic photodetectors of the pixel.

4. The pixel according to claim 1, wherein said organic photodetectors are coplanar.

5. The pixel according to claim 1, wherein said organic photodetectors are separated from one another by a dielectric.

6. The pixel according to claim 1, wherein each organic photodetector comprises a first electrode, separate from first electrodes of the other organic photodetectors, formed at the surface of the CMOS support.

7. The pixel according to claim 6, wherein each first electrode is coupled to a readout circuit, each readout circuit comprising three transistors formed in the CMOS support.

8. The pixel according to claim 1, wherein said organic photodetectors estimate a distance by time of flight.

9. The pixel according to claim 1, wherein the pixel operates:
in a portion of the infrared spectrum;
in structured light;
in high dynamic range imaging, HDR; and/or
with a background suppression.

10. The image sensor according to claim 2, wherein each pixel further comprises, under the lens, a color filter giving way to electromagnetic waves in a frequency range of the visible spectrum and in the infrared spectrum.

11. The image sensor according to claim 10, wherein the image sensor captures a color image.

12. The pixel according to claim 1, wherein the pixel comprises only four organic photodetectors including:
the first organic photodetector;
the second organic photodetector; and
two third organic photodetectors.

13. The pixel according to claim 12, wherein the first organic photodetector, the second organic photodetector, and the third organic photodetectors are square-shaped and are jointly inscribed within a square.

14. The pixel according to claim 12, wherein each organic photodetector comprises a first electrode, separate from first electrodes of the other organic photodetectors, formed at the surface of the CMOS support and wherein:
the first organic photodetector is connected to a second electrode;
the second organic photodetector is connected to a third electrode; and
the third organic photodetectors are connected to a same fourth electrode.

15. The pixel according to claim 12, wherein:
the first organic photodetector and the second organic photodetector comprise a first active layer made of a same first material; and
the third organic photodetectors comprise a second active layer made of a second material.

16. The pixel according to claim 15, wherein the first material is identical to the second material, said material being capable of absorbing the electromagnetic waves of the visible spectrum and of part of the infrared spectrum.

17. The pixel method according to claim 15, wherein the first material is different from the second material, said first material being capable of absorbing the electromagnetic waves of part of the infrared spectrum and said second material being capable of absorbing the electromagnetic waves of the visible spectrum.

18. The image sensor according to claim 20, wherein:
the second electrode is common to all the first organic photodetectors of the pixels of the sensor;
the third electrode is common to all the second organic photodetectors of the pixels of the sensor; and
the fourth electrode is common to all the third organic photodetectors of the pixels of the sensor.

19. The image sensor according to claim 2, wherein each pixel comprises only four organic photodetectors including:
the first organic photodetector;
the second organic photodector; and
two third organic photodetectors.

20. The image sensor according to claim 19, wherein each organic photodetector comprises a first electrode, separate from first electrodes of the other organic photodetectors, formed at the surface of the CMOS support, and for each pixel:
the first organic photodetector is connected to a second electrode;
the second organic photodetector is connected to a third electrode; and
the third organic photodetectors are connected to a same fourth electrode.

21. A method of manufacturing the image sensor according to claim 2, comprising steps of:
providing a CMOS support;
forming at least two organic photodetectors per pixel; and
forming a same lens vertically in line with the organic photodetectors of each pixel.
